(19) United States
(12) Patent Application Publication
(10) Pub. No.: US 2014/0239349 A1
(43) Pub. Date: Aug. 28, 2014

(54) Drain Pad Having a Reduced Termination Electric Field

(71) Applicant: International Rectifier Corporation, El Segundo, CA (US)

(72) Inventors: Michael A. Briere, Scottsdale, AZ (US); Reenu Garg, Torrance, CA (US)

(73) Assignee: International Rectifier Corporation, El Segundo, CA (US)

(21) Appl. No.: 14/185,646

(22) Filed: Feb. 20, 2014

Related U.S. Application Data
(60) Provisional application No. 61/769,037, filed on Feb. 25, 2013.

(51) Int. Cl. H01L 29/417; H01L 29/778

(52) U.S. Cl. CPC H01L 29/41758; H01L 29/778
USPC 257/194

(57) ABSTRACT

In an exemplary implementation, a semiconductor device includes a drain pad on a semiconductor substrate, the drain pad being coupled to a plurality of drain fingers. The semiconductor device further includes a source pad on the semiconductor substrate, the source pad being coupled to a plurality of source fingers. The plurality of source fingers is interdigitated with the plurality of drain fingers. Furthermore, an outer corner of the drain pad has a gradual transition between adjoining sides of the drain pad. The gradual transition between the adjoining sides of the drain pad reduces a termination electric field at the outer corner of the drain pad. Furthermore, the gradual transition between the adjoining sides of the drain pad increases the breakdown voltage of the semiconductor device.

The present application claims the benefit of and priority to U.S. Provisional Patent Application Ser. No. 61/769,037, filed on Feb. 25, 2013 and entitled “Robust Drain Pad Layout.” The disclosure of this application is hereby incorporated fully by reference into the present application.

### BACKGROUND

I. Definition

As used herein, the phrase “group III-V” refers to a compound semiconductor including at least one group III element and at least one group V element. By way of example, a III-N semiconductor may take the form of a III-Nitride semiconductor. “III-Nitride” or “III-N” refers to a compound semiconductor that includes nitrogen and at least one group III element such as aluminum (Al), gallium (Ga), indium (In), and boron (B), and including but not limited to any of its alloys, such as aluminum gallium nitride (AlₓGa₍₁₋ₓ₎N), indium gallium nitride (In_{y}Ga_{(1-y)}N), aluminum indium gallium nitride (AlₓIn_{y}Ga_{(1-x-y)}N), gallium arsenide phosphide nitride (GaAsₐP_{b}N_{(1-a-b)}), aluminum indium gallium arsenide phosphide nitride (AlₓIn_{y}Ga_{(1-x-y)}AsₐP_{b}N_{(1-a-b)}), for example. III-Nitride also refers generally to any polarity including but not limited to Ga-polar, N-polar, semi-polar, or non-polar crystal orientations. A III-Nitride material may also include either the Wurtzitic, Zincblende, or mixed polytypes, and may include single-crystal, monocrystalline, polycrystalline, or amorphous structures. Gallium nitride or GaN, as used herein, refers to a III-Nitride compound semiconductor wherein the group III element or elements include some or a substantial amount of gallium, but may also include other group III elements in addition to gallium. A III-N or a GaN transistor may also refer to a composite high voltage enhancement mode transistor that is formed by connecting the III-N or the GaN transistor in cascode with a lower voltage group IV transistor.

In addition, as used herein, the phrase “group IV” refers to a semiconductor that includes at least one group IV element such as silicon (Si), germanium (Ge), and carbon (C), and may also include compound semiconductors such as silicon germanium (SiGe) and silicon carbide (SiC), for example. Group IV also refers to semiconductor materials which include more than one layer of group IV elements, or doping of group IV elements to produce strained group IV materials, and may also include group IV based composite substrates such as silicon on insulator (SOI), separation by implantation of oxygen (SIMOX) process substrates, and silicon on sapphire (SOS), for example.

It is noted that, as used herein, the terms “low voltage” or “LV” in reference to a transistor or switch describes a transistor or switch with a voltage range of up to approximately fifty volts (50V). It is further noted that use of the term “midvoltage” or “MV” refers to a voltage range from approximately fifty volts to approximately two hundred volts (approximately 50V to 200V). Moreover, the term “high voltage” or “HV,” as used herein, refers to a voltage range from approximately two hundred volts to approximately twelve hundred volts (approximately 200V to 1200V), or higher.

II. Background Art

III-N hetero structure field-effect transistors (III-N HFETs), such as III-N high electron mobility transistors (III-N HEMTs), are often utilized in high voltage and high power applications. For example, a III-Nitride HEMT may be utilized as a power transistor to provide power switching and/or amplification functions to a circuit. By providing the power transistor as a III-N HFET, the power transistor can have a lateral conduction topology in which drain, source, and gate electrodes of the power transistor are formed on one side of a semiconductor wafer or die.

A III-N HFET can have a layout where drain and source fingers are interdigitated and are surrounded by a gate coupled to a gate pad. The drain and source finger electrodes are coupled to respective drain and source pads. In a high voltage transistor, outer corners of the drain pad are susceptible to failure over time due to formation of a high termination electric field at a periphery of the high voltage transistor.

### SUMMARY

A drain pad having a reduced termination electric field, substantially as shown in and/or described in connection with at least one of the figures, and as set forth more completely in the claims.

### BRIEF DESCRIPTION OF THE DRAWINGS

FIG. 1A shows a layout view of a semiconductor device.

FIG. 1B shows a magnified view of a drain pad corner region of a semiconductor device.

FIG. 2A shows a layout view of an exemplary semiconductor device, according to an implementation disclosed in the present application.

FIG. 2B shows a magnified view of an exemplary drain pad corner region of a semiconductor device, according to an implementation disclosed in the present application.

FIG. 3A shows an exemplary drain pad corner region of a semiconductor device, according to an implementation disclosed in the present application.

FIG. 3B shows an exemplary drain pad corner region of a semiconductor device, according to an implementation disclosed in the present application.

### DETAILED DESCRIPTION

The following description contains specific information pertaining to implementations in the present disclosure. The drawings in the present application and their accompanying detailed description are directed to merely exemplary implementations. Unless noted otherwise, like or corresponding elements among the figures may be indicated by like or corresponding reference numerals. Moreover, the drawings and illustrations in the present application are generally not to scale, and are not intended to correspond to actual relative dimensions.

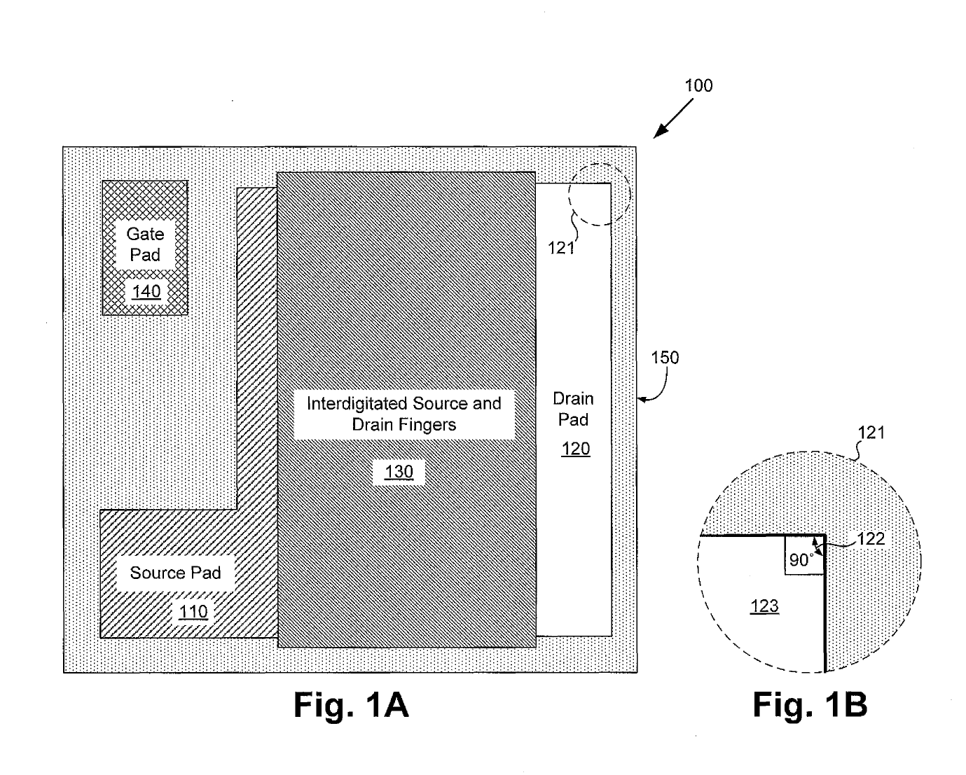

FIG. 1A shows a layout view of a semiconductor device. In particular, FIG. 1A shows semiconductor device 100, which is a transistor that includes source pad 110, drain pad 120, gate pad 140, and semiconductor die 150. Interdigitated source and drain finger region 130 of semiconductor die 150 is situated between source pad 110 and drain pad 120.

Interdigitated source and drain finger region 130 of semiconductor die 150 can provide an active region of semiconductor device 100. In interdigitated source and drain finger region 130, source and drain fingers are interdigitated and are surrounded by a gate that is electrically coupled to gate pad 140. The source fingers of interdigitated source and drain finger region 130 may terminate on source pad 110, while the drain fingers of interdigitated source and drain finger region 130 may terminate on drain pad 120. Gate pad 140 is situated away from source pad 110 and drain pad 120.

Referring to FIG. 1B with FIG. 1A, FIG. 1B shows a magnified view of a drain pad corner region of a semiconductor device. In particular, FIG. 1B shows a magnified view of drain pad corner region 121 of FIG. 1A. As shown in FIGS. 1A and 1B, each outer corner of drain pad 120, such as outer corner 123, is formed by a vertex having interface angle 122 that is substantially 90 degrees. The outer corners of drain pad 120, including outer corner 123, are susceptible to failure over time due to a high termination electric field formed at the periphery of semiconductor device 100. Thus, the robustness of semiconductor device 100 may be compromised. As a result, semiconductor device 100 may break down, become unstable, and/or fail catastrophically, particularly under high voltage operation.

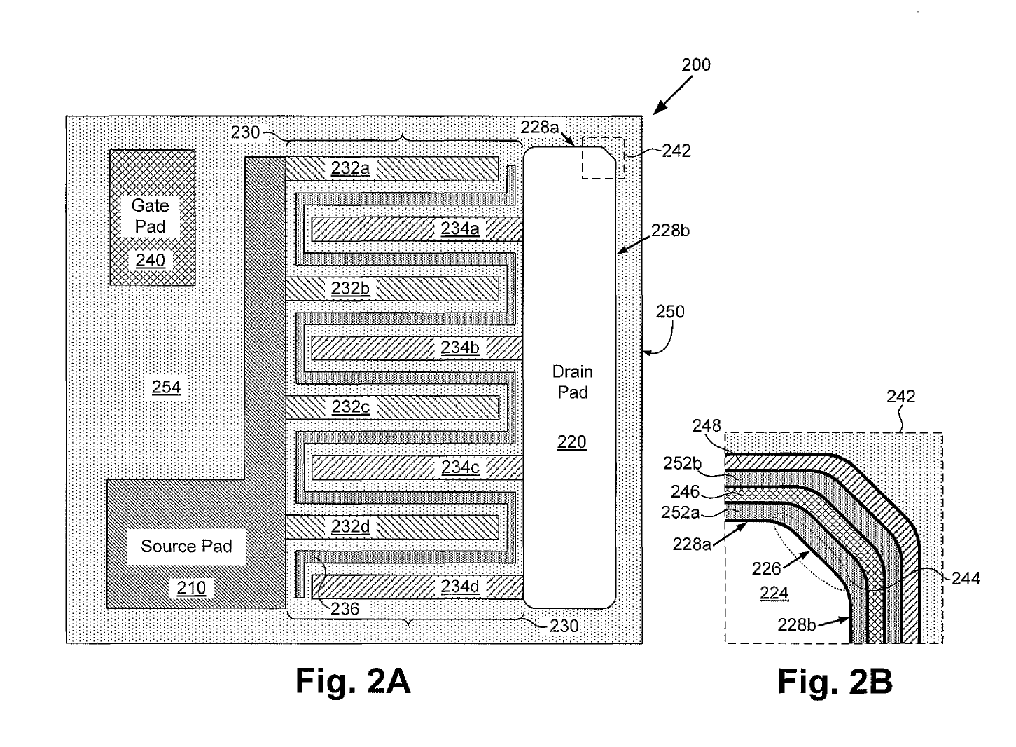

Referring now to FIG. 2A, FIG. 2A shows a layout view of an exemplary semiconductor device, according to an implementation disclosed in the present application. In particular, FIG. 2A shows semiconductor device 200, which is a transistor that includes source pad 210, drain pad 220, gate pad 240, and semiconductor substrate 250. Interdigitated source and drain finger region 230 of semiconductor substrate 250 is situated between source pad 210 and drain pad 220.

In the present implementation, semiconductor device 200 is a field-effect transistor (FET). Semiconductor device 200 can be a high voltage transistor implemented as various types of FETs, such as an insulated-gate FET (IGFET) or a heterostructure FET (HFET). In some implementations, semiconductor device 200 is a metal-insulator-semiconductor FET (MISFET), such as a metal-oxide-semiconductor FET (MOSFET).

Also, in some implementations, semiconductor device 200 is a high electron mobility transistor (HEMT), which includes a two-dimensional electron gas (2DEG) that may be utilized as a conduction channel in an active region of semiconductor device 200. For example, semiconductor device 200 can be a III-Nitride HEMT having heterostructure 254. Suitable III-Nitride materials for semiconductor device 200 include gallium nitride (GaN) and/or its alloys, such as aluminum gallium nitride (AlGaN), indium gallium nitride (InGaN), and aluminum indium gallium nitride (AlInGaN). For example, heterostructure 254 can comprise an AlGaN/GaN interface, with a top surface of an AlGaN layer of the AlGaN/GaN interface being shown in FIG. 2A. III-Nitride materials are semiconductor compounds that have a relatively wide and direct bandgap, strong piezoelectric polarizations, can enable high breakdown fields, and can create the 2DEG at an interface between, for example, AlGaN and GaN layers.

Interdigitated source and drain finger region 230 of semiconductor substrate 250 can provide an active region of semiconductor device 200. Interdigitated source and drain finger region 230 includes source fingers 232a, 232b, 232c, and 232d interdigitated with drain fingers 234a, 234b, 234c, and 234d on semiconductor substrate 250. Source fingers 232a, 232b, 232c, and 232d and drain fingers 234a, 234b, 234c, and 234d are surrounded by gate 236 that is electrically coupled to gate pad 240. Interdigitated source and drain finger region 230 includes a conduction channel in semiconductor substrate 250 that may be formed from 2DEG. Interdigitated source and drain finger region 230 is merely exemplary, and may include more or fewer source and drain fingers than is shown in FIG. 2A.

Source pad 210 is on semiconductor die 250 and is electrically coupled to source fingers 232a, 232b, 232c, and 232d. Similarly, drain pad 220 is on semiconductor die 250 and is electrically coupled to drain fingers 234a, 234b, 234c, and 234d. Gate pad 240 is situated away from source pad 210 and drain pad 220.

Referring to FIG. 2B with FIG. 2A, FIG. 2B shows a magnified view of a exemplary drain pad corner region of a semiconductor device, according to an implementation disclosed in the present application. In particular, FIG. 2B shows a magnified view of drain pad corner region 242 of FIG. 2A. As shown in FIGS. 2A and 2B, each outer corner of drain pad 220, such as outer corner 224, has a gradual transition between adjoining sides of drain pad 220. For example, outer corner 224 has gradual transition 226 between adjoining sides 228a and 228b of drain pad 220. As shown, adjoining sides 228a and 228b of drain pad 220 are substantially perpendicular. Furthermore, adjoining side 228b of drain pad 220 extends alongside interdigitated source and drain finger region 230. In particular, adjoining side 228b of drain pad 220 extends alongside each of drain fingers 234a, 234b, 234c, and 234d.

Gradual transition 226 prevents an interface angle (e.g. interface angle 122 of FIG. 1B) between adjoining sides 228a and 228b that is substantially 90 degrees. As such, gradual transition 226 reduces termination electric field 244 at outer corner 224 of drain pad 220, and furthermore, increases the reliable maximum voltage of semiconductor device 200. As a result, semiconductor device 200 is significantly less likely than semiconductor device 100 to break down, become unstable, and/or fail catastrophically, particularly under high voltage operation.

Semiconductor device 200 optionally includes a gate coupled edge termination and/or a source coupled edge termination, which can each include metal layers. The gate and source coupled edge terminations extend around the periphery of semiconductor device 200. Dielectric regions 252a and 252b are isolating the source coupled edge termination, the gate coupled edge termination, and drain pad 220 from one another. As shown in FIG. 2B, outer corner 224 of drain pad 220 is adjacent to outer corner 246 of the gate coupled edge termination and outer corner 248 of the source coupled edge termination. Outer corners 246 and 248 can optionally track outer corner 224 of drain pad 220, as shown, so as to have gradual transitions between adjoining sides similar to gradual transition 226. However, in other implementations, outer corners 246 and 248 can have gradual transitions that are different from one another, and/or from gradual transition 226.

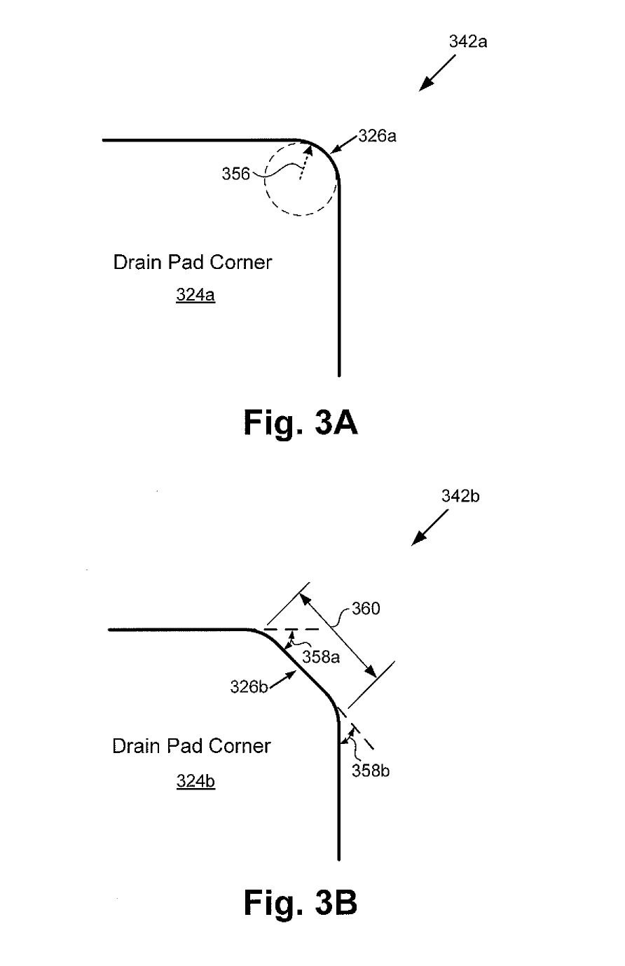

Referring now to FIG. 3A, FIG. 3A shows an exemplary drain pad corner region of a semiconductor device, according to an implementation disclosed in the present application. In FIG. 3A, drain pad corner region 342a can correspond to drain pad corner region 242 of FIGS. 2A and 2B.

In drain pad corner region 342a, outer corner 324a has gradual transition 326a, corresponding to gradual transition 226 in FIG. 2B. Gradual transition 326a has a substantially rounded geometry. As a result, there are no sharp discontinuities in gradual transition 326a. The substantially rounded geometry of gradual transition 326a eases termination electric fields (e.g. termination electric field 244 of FIG. 2A) at outer corner 324a. Furthermore, gradual transition 326a has a substantially continuously curved geometry. As shown, gradual transition 326a is a circular segment corresponding to a segment of a circle having radius of curvature 356, by way of example.

Referring now to FIG. 3B, FIG. 3B shows an exemplary drain pad corner region of a semiconductor device, according to an implementation disclosed in the present application. In FIG. 3B, drain pad corner region 342b can correspond to drain pad corner region 242 of FIGS. 2A and 2B.

In drain pad corner region 342b, outer corner 324b has gradual transition 326b, corresponding to gradual transition 226 in FIG. 2B. Similar to gradual transition 326a, gradual transition 326b has a substantially rounded geometry. Gradual transition 326b can be of length 360, where length 360 is, for example, less than approximately ten micrometers. FIG. 3B illustrates that gradual transition 226 of FIG. 2B may include at least two interface angles. For example, gradual transition 326b includes interface angles 358a and 358b. Interface angles 358a and 358b are each less than 90 degrees. Where gradual transition 326b includes more than two interface angles, each interface angle can be less than 90 degrees. In some implementations, the sum of all interface angles of gradual transition 326b is approximately 90 degrees.

Referring again to FIGS. 2A and 2B, in semiconductor device 200, where gradual transition 226 is similar to gradual transition 326a in FIG. 3A, outer corners 246 and 248 can include gradual transitions, which are similar to gradual transition 326a. Furthermore, where gradual transition 226 is similar to gradual transition 326b in FIG. 3B, outer corners 246 and 248 can include gradual transitions, which are similar to gradual transition 326b. It is further noted that each drain pad corner region of drain pad 220 can optionally be similar to any of drain pad corner regions 242, 342a, and 342b described above. Also, in some implementations, the drain pad corner regions of drain pad 220 are optionally substantially similar with respect to one another.

Thus, as described with respect to FIGS. 2A, 2B, 3A, and 3B, implementations of the present disclosure provide for a semiconductor device in which an outer corner of a drain pad of the semiconductor device includes a gradual transition between adjoining sides of the drain pad. The gradual transition prevents an interface angle between the adjoining sides of the drain pad that is substantially 90 degrees. As such, the gradual transition reduces a termination electric field at the outer corner of the drain pad, and furthermore, increases maximum reliable voltage of the semiconductor device.

From the above description it is manifest that various techniques can be used for implementing the concepts described in the present application without departing from the scope of those concepts. Moreover, while the concepts have been described with specific reference to certain implementations, a person of ordinary skill in the art would recognize that changes can be made in form and detail without departing from the scope of those concepts. As such, the described implementations are to be considered in all respects as illustrative and not restrictive. It should also be understood that the present application is not limited to the particular implementations described above, but many rearrangements, modifications, and substitutions are possible without departing from the scope of the present disclosure.

1. A semiconductor device comprising:
a drain pad on a semiconductor substrate, said drain pad coupled to a plurality of drain fingers;
a source pad on said semiconductor substrate, said source pad coupled to a plurality of source fingers;
said plurality of source fingers interdigitated with said plurality of drain fingers;
an outer corner of said drain pad having a gradual transition between adjoining sides of said drain pad.

2. The semiconductor device of claim 1, wherein one of said adjoining sides of said drain pad extends alongside each of said plurality of drain fingers.

3. The semiconductor device of claim 1, wherein said adjoining sides of said drain pad are substantially perpendicular.

4. The semiconductor device of claim 1, wherein said gradual transition comprises a substantially rounded geometry.

5. The semiconductor device of claim 1, wherein said gradual transition comprises at least two interface angles.

6. The semiconductor device of claim 1, wherein said outer corner of said drain pad is adjacent to an outer corner of a gate coupled edge termination.

7. The semiconductor device of claim 6, wherein said outer corner of said gate coupled edge termination is adjacent to an outer corner of a source coupled edge termination.

8. The semiconductor device of claim 1, wherein said gradual transition between said adjoining sides of said drain pad reduces a termination electric field at said outer corner of said drain pad.

9. The semiconductor device of claim 1, wherein said gradual transition between said adjoining sides of said drain pad increases a maximum reliable voltage of said semiconductor device.

10. The semiconductor device of claim 1, wherein said semiconductor device is a III-Nitride high-electron-mobility transistor (HEMT).

11. The semiconductor device of claim 1, wherein said semiconductor device is a high voltage transistor.

12. A transistor comprising:
a drain pad on a semiconductor die;
a source pad on said semiconductor die;
an interdigitated source and drain finger region of said die situated between said drain pad and said source pad and comprising a plurality of source fingers coupled to said source pad and a plurality of drain fingers coupled to said drain pad;
an outer corner of said drain pad having a gradual transition between adjoining sides of said drain pad, so as to reduce a termination electric field at said outer corner of said drain pad.

13. The semiconductor device of claim 12, wherein one of said adjoining sides of said drain pad extends alongside said interdigitated source and drain finger region.

14. The semiconductor device of claim 12, wherein said adjoining sides of said drain pad are substantially perpendicular.

15. The semiconductor device of claim 12, wherein said gradual transition comprises a substantially rounded geometry.

16. The semiconductor device of claim 12, wherein said gradual transition comprises at least two interface angles.

17. The semiconductor device of claim 12, wherein said outer corner of said drain pad is adjacent to an outer corner of a gate coupled edge termination.

18. The semiconductor device of claim 17, wherein said outer corner of said gate coupled edge termination is adjacent to an outer corner of a source coupled edge termination.

19. The semiconductor device of claim 12, wherein said gradual transition between said adjoining sides of said drain pad increases a maximum reliable voltage of said semiconductor device.

20. The semiconductor device of claim 12, wherein said semiconductor device is a III-Nitride HEMT.
